(19) United States
(12) Patent Application Publication
(10) Pub. No.: US 2003/0042502 A1
(43) Pub. Date: Mar. 6, 2003

(54) Heterojunction field effect transistor and manufacturing method therefor

(75) Inventors: Hajime Ohnishi, Chino-shi (JP); Hiroyuki Nakano, Shiga-ken (JP)

Correspondence Address: Keating & Bennett LLP, Suite 312, 10400 Eaton Place, Fairfax, VA, 22030, US

(73) Assignee: Murata Manufacturing Co., Ltd., Nagaokakyo-shi (JP)

(21) Appl. No.: 10/197,826

(22) Filed: Jul. 19, 2002

(30) Foreign Application Priority Data
Aug. 29, 2001 (JP) 2001-259936

(51) Int. Cl. H01L 31/0328

(52) U.S. Cl. 257/192

(57) ABSTRACT

A heterojunction field effect transistor has a high forward withstand voltage between a gate and a source, and includes a channel layer, a carrier supply layer, a first Schottky contact layer preferably made of AlGaAs, a second Schottky contact layer which preferably made of AlGaAs having an Al component ratio that is lower than that of the first Schottky contact layer, and a contact layer, which are disposed in that order on a semiconductor substrate. A groove is formed by removing a portion of the contact layer. A gate electrode extending from a region on a portion of the surface of the second Schottky contact layer to the surface or the inside of the first Schottky contact layer is formed in the groove. Accordingly, the Schottky barrier height is increased, and a high forward withstand voltage between the gate and the source is achieved. In addition, since the distance between the gate electrode and the channel layer is decreased, a high mutual conductance is achieved.

### BACKGROUND OF THE INVENTION

1. Field of the Invention

The present invention relates to heterojunction field effect transistors, and more particularly, to a heterojunction field effect transistor having a Schottky contact layer between the channel layer and the gate electrode.

2. Description of the Related Art

In heterojunction field effect transistors, a Schottky contact layer having a Schottky contact with a gate electrode in order to enhance the forward withstand voltage between the gate and the source has been generally made of AlGaAs, which can increase the Schottky barrier height, in many cases. Since the Schottky barrier height is increased with increases in the aluminum (Al) component ratio relative to AlGaAs, in order to enhance the forward withstand voltage between the gate and the source, AlGaAs having a high Al component ratio is preferably used. However, since oxidation is likely to occur when the Al component ratio is increased, the Al component ratio is controlled generally in the range of about 0.2 to about 0.4, and as a result, it has been difficult to obtain a high forward withstand voltage.

One method for solving this problem has been disclosed in Japanese Unexamined Patent Application Publication No. 9-246525.

FIG. 8 is a cross-sectional view of a heterojunction field effect transistor disclosed in the above-mentioned publication.

As shown in FIG. 8, a heterojunction field effect transistor 40 includes a buffer layer 2, a channel layer 3, a first Schottky contact layer 5, a second Schottky contact layer 6, and a contact layer 7 which are disposed in that order on a semiconductor substrate 1. A gate electrode 10 is disposed in the region on a portion of the surface of the second Schottky contact layer 6. In addition, a source electrode 8a and a drain electrode 8b are disposed on both sides of the gate electrode 10.

In this structure, on the first Schottky contact layer 5 made of AlGaAs, the second Schottky contact layer 6 made of AlGaAs having an Al component ratio that is lower than that of the first Schottky contact layer 5 is disposed. Accordingly, the first Schottky contact layer 5 is not exposed, and hence, oxidation can be prevented. In addition, since the Al component ratio of the first Schottky contact layer 5 can be increased, an advantage can be achieved in that the forward withstand voltage between the gate and the source is increased.

In the conventional heterojunction field effect transistor 40, since the gate electrode 10 is in Schottky contact with the second Schottky contact layer 6, which is made of AlGaAs having a lower Al component ratio, the forward withstand voltage between the gate and the source is increased. However, the forward withstand voltage has not been increased to a satisfactory level. In addition, since the distance between the gate electrode 10 and the channel layer 3 is increased, modulation of gate voltages in accordance with input signals is not effectively transmitted to the channel layer 3, and there has been a problem in that the gm (mutual conductance) is decreased.

### SUMMARY OF THE INVENTION

In order to overcome the problems described above, preferred embodiments of the present invention provide a greatly improved heterojunction field effect transistor which has a very high forward withstand voltage between a gate and a source, without suffering any drawbacks.

According to a preferred embodiment of the present invention, a heterojunction field effect transistor includes a semiconductor substrate, a channel layer preferably made of InₓGa₁₋ₓAs (0≦x≦0.3), a carrier supply layer preferably made of AlGaAs, a first Schottky contact layer preferably made of AlGaAs, a second Schottky contact layer preferably made of AlGaAs having an aluminum (Al) component ratio that is lower than that of the first Schottky contact layer, the layers being arranged in that order on the semiconductor substrate, and a gate electrode extending from a region on a portion of the surface of the second Schottky contact layer to the surface or the inside of the first Schottky contact layer.

In addition, in the heterojunction field effect transistor of this preferred embodiment of the present invention, it is preferable that the Al component ratio of the first Schottky contact layer is more than about 0.3, and that the Al component ratio of the second Schottky contact layer is about 0.3 or less.

A method for manufacturing a heterojunction field effect transistor, according to another preferred embodiment of the present invention, includes the steps of forming a channel layer preferably made of InₓGa₁₋ₓAs (0≦x≦0.3) on a semiconductor substrate, forming a carrier supply layer preferably made of AlGaAs on the channel layer, forming a first Schottky contact layer preferably made of AlGaAs on the carrier supply layer, and forming a second Schottky contact layer which is preferably made of AlGaAs having an Al component ratio lower than that of the first Schottky contact layer, forming a layer preferably made of a metal for forming a gate electrode in a region on a portion of the surface of the second Schottky contact layer, and performing heat treatment to diffuse the metal to the surface or the inside of the first Schottky contact layer, whereby the gate electrode is formed.

In addition, in the method for manufacturing the heterojunction field effect transistor, according to the preferred embodiments of the present invention, it is preferable that the thickness of the layer made of the metal for forming the gate electrode is not less than the about half of that of the second Schottky contact layer and is less than about half of the total thickness of the first Schottky contact layer and the second Schottky contact layer.

Furthermore, in the method for manufacturing the heterojunction field effect transistor, according to the preferred embodiments of the present invention, the metal for forming the gate electrode may comprise platinum (Pt).

When the heterojunction field effect transistor of the preferred embodiments of the present invention is formed as described above, a high forward withstand voltage between the gate and the source and a high gm is achieved.

Other features, elements, characteristics and advantages of the present invention will become more apparent from the following detailed description of the preferred embodiments of the present invention with reference to the attached drawings.

### BRIEF DESCRIPTION OF THE DRAWINGS

FIG. 1 is a cross-sectional view of a heterojunction field effect transistor according to a preferred embodiment of the present invention;

FIG. 2 is a graph showing the forward voltage-current characteristics of a heterojunction field effect transistor according to a preferred embodiment of the present invention and a conventional device;

FIG. 3 is a view for illustrating one step of a method for manufacturing a heterojunction field effect transistor according to a preferred embodiment of the present invention;

FIG. 4 is a view showing a step following the step shown in FIG. 3 of the manufacturing method;

FIG. 5 is a view showing a step following the step shown in FIG. 4 of the manufacturing method;

FIG. 6 is a view showing a step following the step shown in FIG. 5 of the manufacturing method;

FIG. 7 is-a view showing a step following the step shown in FIG. 6 of the manufacturing method; and

FIG. 8 is a cross-sectional view of a conventional heterojunction field effect transistor.

### DETAILED DESCRIPTION OF PREFERRED EMBODIMENTS

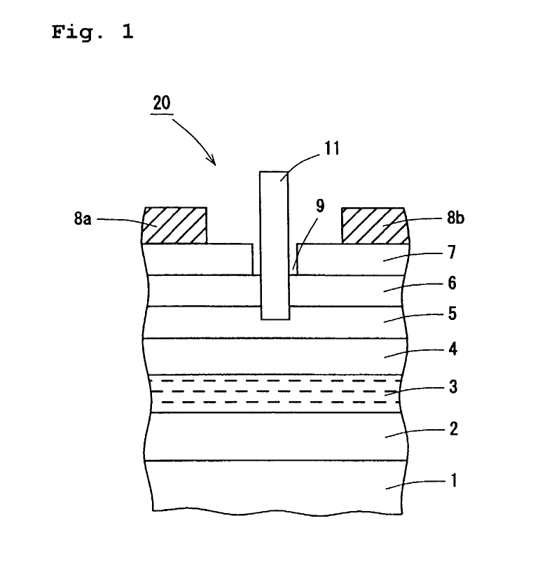

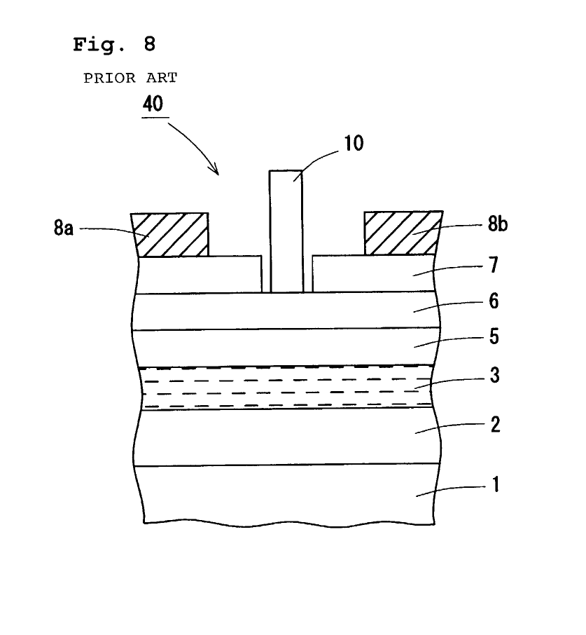

FIG. 1 is a cross-sectional view of a heterojunction field effect transistor according to a preferred embodiment of the present invention. In FIG. 1, the same reference numerals of the constituent elements in FIG. 8 designate the same or equivalent constituent elements in this figure.

As shown in FIG. 1, a heterojunction field effect transistor 20 preferably includes a buffer layer 2 preferably made of undoped GaAs, a channel layer 3 preferably made of undoped In_{0.2}Ga_{0.8}As, a carrier supply layer 4 preferably made of silicon doped Al_{0.25}Ga_{0.75}As, a first Schottky contact layer 5 preferably made of undoped Al_{0.9}Ga_{0.1}As, a second Schottky contact layer 6 preferably made of silicon doped Al_{0.2}Ga_{0.8}As, and a contact layer 7 preferably made of silicon doped GaAs, which are arranged in that order on a semiconductor substrate 1, which is preferably made of semi-insulating GaAs.

A groove 9 is preferably formed by removing a portion of the contact layer 7, and at the bottom surface of the groove 9, the second Schottky contact layer 6 is exposed. In the groove 9, a gate electrode 11 extending from a portion of the surface of the second Schottky contact layer 6 to the inside of the first Schottky contact layer 5 is formed, and a source electrode 8a and a drain electrode 8b each ohmically connected to the channel layer 3 are formed on the contact layer 7 at both sides of the gate electrode 11. In this structure, the Al component ratio of AlGaAs of the first Schottky contact layer 5 is preferably about 0.9, and the Al component ratio of AlGaAs of the second Schottky contact, layer 6 is preferably about 0.2.

In the heterojunction field effect transistor 20 thus formed, since the gate electrode 11 is in Schottky contact with the first Schottky contact layer 5, which is preferably made of AlGaAs having a high Al component ratio, the Schottky barrier height is greatly increased, and hence, a high forward withstand voltage between the gate and the source is achieved. In addition, since the distance between the channel layer 3 and the gate electrode 11 is decreased, modulation of gate voltages in accordance with input signals is effectively transmitted to the channel layer 3, and hence, a high gₘ can be obtained.

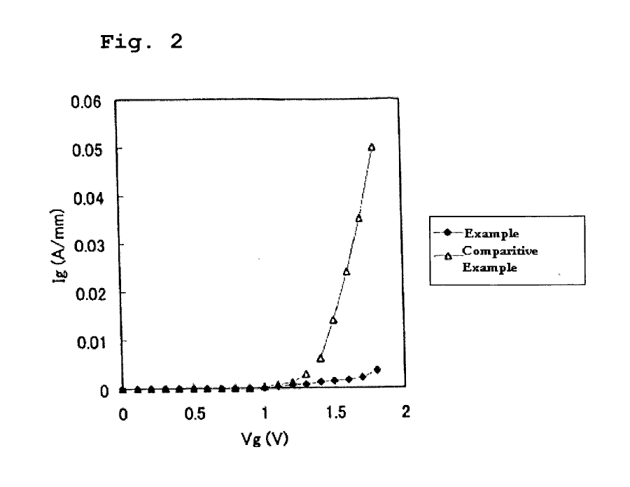

A graph of FIG. 2 shows the forward voltage-current characteristics between the gate and the source of the heterojunction field effect transistor 20 according to an example of preferred embodiments of the present invention. In this graph, the transverse axis represents a forward applied voltage Vg (V) between the gate and the source, and the vertical axis represents a corresponding forward current Ig (A/mm) in that term.

FIG. 2 also shows the forward voltage-current characteristics of the conventional heterojunction field effect transistor 40. In the figure, the characteristics of the heterojunction field effect transistor 20 according to the example of preferred embodiments of the present invention are represented by square marks, and the characteristics of the conventional heterojunction field effect transistor 40, which is a comparative example, are represented by triangular marks.

As shown in FIG. 2, in the conventional heterojunction field effect transistor 40 according to the comparative example, when the forward applied voltage Vg exceeds 1 volts (V), an abrupt increase of forward current Ig (A/mm) can be increased. However, in contrast, in the heterojunction field effect transistor 20 according to the example of preferred embodiments of the present invention, the forward current Ig (A/mm) can not be increased any more. That is, FIG. 2 shows that the heterojunction field effect transistor 20 of preferred embodiments of the present invention has a higher forward withstand voltage than that of the conventional one.

In this preferred embodiment, the Al component ratio of AlGaAs of the second Schottky contact layer 6 is not limited to approximately 0.2 and may be about 0.3 or less, which is the Al component ratio at which oxidation is not liable to occur. In addition, the Al component ratio of AlGaAs of the first Schottky contact layer 5 is not limited to approximately 0.9. The first Schottky contact layer 5 having an Al component ratio that is higher than that of the second Schottky contact layer 6 may be used, and the Al component ratio is preferably about 0.7 or more. Furthermore, the In component ratio of InGaAs of the channel layer 3 is not limited to approximately 0.2.

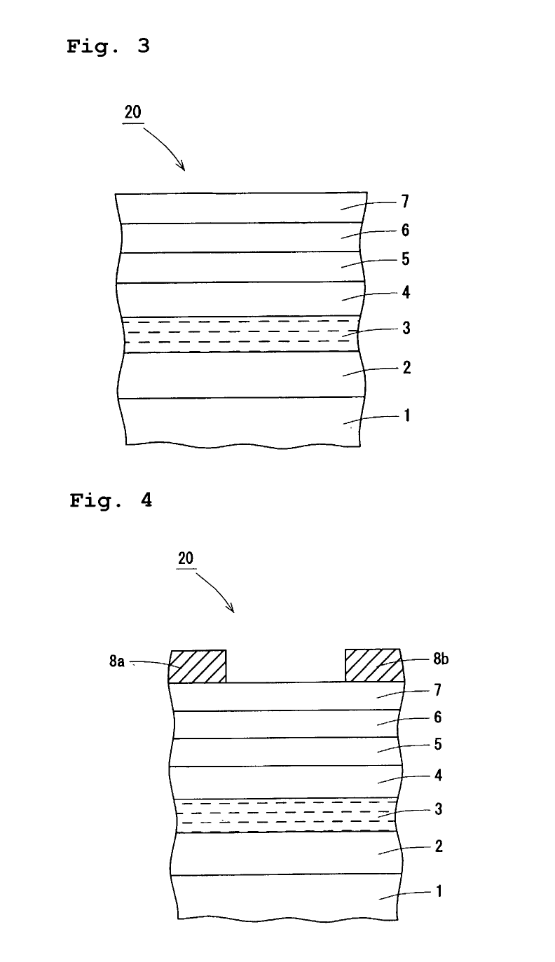

FIGS. 3 to 7 are views for illustrating a method for manufacturing the heterojunction field effect transistor 20 according to another preferred embodiment of the present invention. The same reference numerals of the constituent elements shown in FIG. 1 designate the same or equivalent elements shown in FIGS. 3 to 7.

As shown in FIG. 3, by a crystal growth method including a MBE (molecular beam epitaxial) method, a MOCVD (metal organic chemical vapor deposition) method, a MOVPE (metal organic vapor-phase epitaxial) method, or other suitable method, the heterojunction field effect transistor 20 includes the buffer layer 2 preferably made of undoped GaAs having a thickness of about 500 nm, the channel layer 3 preferably made of undoped In_{0.2}Ga_{0.8}As having a thickness of about 10 nm, the carrier supply layer 4 preferably made of silicon doped Al_{0.25}Ga_{0.75}As having a thickness of about 20 nm, the first Schottky contact layer 5 preferably made of undoped Al_{0.9}Ga_{0.1}As having a thickness of about 4 nm, the second Schottky contact layer 6 preferably made of silicon doped Al_{0.2}Ga_{0.8}As having a thickness of about 10 nm, and the contact layer 7 preferably made of silicon doped GaAs having a thickness of about 50 nm, which are formed in that order on the semiconductor substrate 1, which is preferably made of semi-insulating GaAs.

In this preferred embodiment, the compositions and the thicknesses of the compound semiconductor layers are described by way of example and are not limited thereto.

Next, as shown in FIG. 4, ohmic electrodes (AuGe/Ni/Au) used as the source electrode 8a and the drain electrode 8b are formed by a lift-off method and are then converted into alloy electrodes by heat treatment at about 400° C. for approximately 2 minutes in a nitrogen atmosphere.

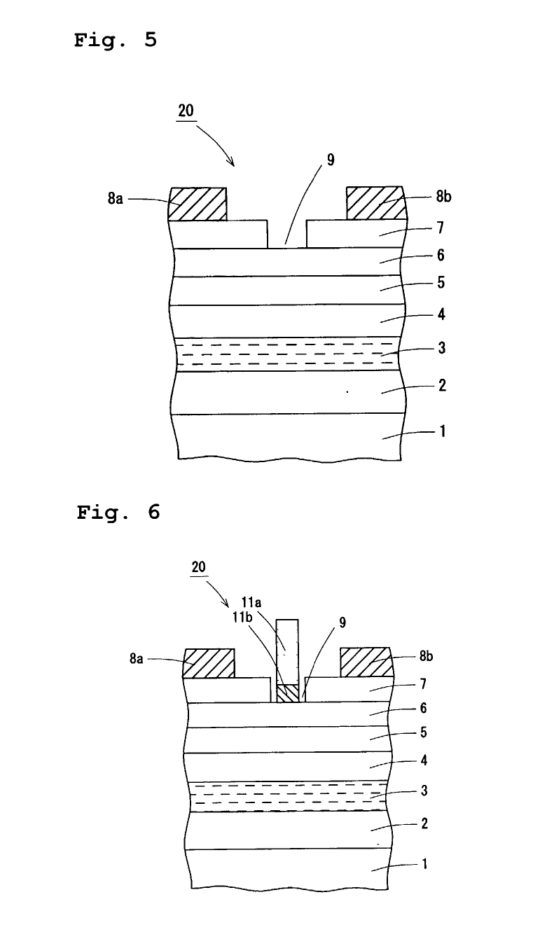

Next, as shown in FIG. 5, a portion of the contact layer 7 preferably made of GaAs is selectively removed by etching, thereby forming the groove 9 between the source electrode 8a and the drain electrode 8b. The groove 9 is preferably formed by an etching method in which an etching rate of GaAs is high and an etching rate of AlGaAs is low, and the etching is stopped at the surface of the second Schottky contact layer 6 preferably made of AlGaAs. The etching described above can be achieved by using a mixed solution of citric acid, aqueous hydrogen peroxide, and water as an etching solution.

Next, as shown in FIG. 6, a layer 11b for forming the gate electrode 11, which is preferably made of platinum (Pt), is formed on a portion of the surface of the second Schottky contact layer 6 in the groove 9 by a lift-off method. In a manner similar to that described above, a metal layer 11a is formed on the Pt layer 11b. This metal layer 11a has a structure that includes, for example, molybdenum (Mo) that is about 5 nm thick, titanium (Ti) that is about 50 nm thick, platinum (Pt) that is about 25 nm thick, and gold (Au) that is about 500 nm thick, formed in that order from the bottom.

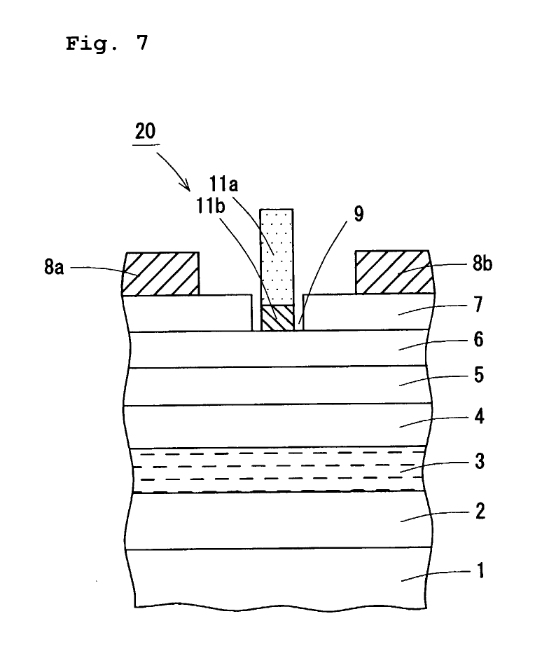

Next, as shown in FIG. 7, by performing heat treatment at approximately 350° C. in a nitrogen atmosphere, the Pt forming the layer located at the bottommost position is diffused into the second Schottky contact layer 6 and the first Schottky contact layer 5, both of which are composed of AlGaAs. In this step, the Pt is diffused to a depth that is about twice the thickness of the Pt layer 11b, that is, the Pt is diffused into the second Schottky contact layer 6 and the first Schottky contact layer 5, both of which are preferably made of AlGaAs. As described above, the thickness of the first Schottky contact layer 5 is preferably about 4 nm and the thickness of the second Schottky contact layer 6 is preferably about 10 nm. Accordingly, when the Pt layer 11b which is the bottommost layer is formed so as to have a thickness Y in the range of from about 5 nm to less than about 7 nm, a Pt diffusion region 11c is formed by diffusion, thereby forming the gate electrode 11 extending to the surface or the inside of the first Schottky contact layer 5.

Accordingly, it is understood that when the thickness of the Pt layer 11b which is the bottommost layer of the gate electrode 11 is not less than about half of that of the second Schottky contact layer 6 and is less than about half of the total thickness of the first Schottky contact layer 5 and the second Schottky contact layer 6, the gate electrode 11 extending to the surface or the inside of the first Schottky contact layer 5 is formed.

According to the steps described above, the heterojunction field effect transistor 20 shown in FIG. 1 can be obtained.

According to the heterojunction field effect transistor of preferred embodiments of the present invention, since the second Schottky contact layer, which is preferably made of AlGaAs and has an Al component ratio that is lower than that of the first Schottky contact layer preferably made of AlGaAs, is formed thereon, and the gate electrode is formed so as to extend to the surface or the inside of the first Schottky contact layer, the Schottky barrier height is increased, and hence, a high forward withstand voltage between the gate and the source can be obtained. In addition, since the distance between the gate electrode and the channel layer is decreased, a high gm can be obtained.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A heterojunction field effect transistor comprising:
a semiconductor substrate;
a channel layer including InₓGa₁₋ₓAs (0≦x≦0.3) disposed on the semiconductor substrate;
a carrier supply layer including AlGaAs disposed on the channel layer;
a first Schottky contact layer including AlGaAs disposed on the carrier supply layer;
a second Schottky contact layer including AlGaAs disposed on the first Schottky contact layer and having an aluminum component ratio that is lower than that of the first Schottky contact layer; and
a gate electrode extending from a region on a portion of the surface of the second Schottky contact layer to one of a surface of the first Schottky contact layer and an interior portion of the first Schottky contact layer.

2. A heterojunction field effect transistor according to claim 1, wherein the aluminum component ratio of the first Schottky contact layer is greater than about 0.3, and the aluminum component ratio of the second Schottky contact layer is equal to or less than about 0.3.

3. A heterojunction field effect transistor according to claim 1, further comprising a buffer layer including undoped GaAs disposed between the semiconductor substrate and the channel layer.

4. A heterojunction field effect transistor according to claim 1, wherein the channel layer is made of undoped In_{0.2}Ga_{0.8}As.

5. A heterojunction field effect transistor according to claim 1, wherein the carrier supply layer is made of silicon doped Al_{0.25}Ga_{0.75}As.

6. A heterojunction field effect transistor according to claim 1, wherein the first Schottky contact layer is made of undoped Al_{0.9}Ga_{0.1}As,

7. A heterojunction field effect transistor according to claim 1, wherein the second Schottky contact layer is made of silicon doped Al_{0.2}Ga_{0.8}As.

8. A heterojunction field effect transistor according to claim 1, wherein the semiconductor substrate is made of semi-insulating GaAs.

9. A heterojunction field effect transistor according to claim 1, wherein the gate electrode is made of platinum.

10. A heterojunction field effect transistor according to claim 1, wherein the thickness of the gate electrode is not less than half of that of the second Schottky contact layer and is less than half of the total thickness of the first Schottky contact layer and the second Schottky contact layer.

11. A heterojunction field effect transistor according to claim 1, further comprising a contact layer having a groove formed therein, the second Schottky contact layer being exposed at the groove formed in the contact layer, and the gate electrode is disposed in the groove.

12. A heterojunction field effect transistor according to claim 11, further comprising a source electrode and a drain electrode each ohmically connected to the channel layer and disposed on the contact the contact layer at both sides of the gate electrode.

13. A heterojunction field effect transistor according to claim 1, wherein the Al component ratio of AlGaAs of the first Schottky contact layer is about 0.9.

14. A heterojunction field effect transistor according to claim 1, wherein the Al component ratio of AlGaAs of the second Schottky contact layer is about 0.2.

15. A heterojunction field effect transistor according to claim 1, wherein the gate electrode is in Schottky contact with the first Schottky contact layer.

16. A method for manufacturing a heterojunction field effect transistor, comprising the steps of:
forming a channel layer including InₓGa₁₋ₓAs (0≦x≦0.3) on a semiconductor substrate;
forming a carrier supply layer including AlGaAs on the channel layer;
forming a first Schottky contact layer including AlGaAs on the carrier supply layer;
forming on the first Schottky contact layer a second Schottky contact layer including AlGaAs having an aluminum component ratio that is lower than that of the first Schottky contact layer;
forming a layer including a metal for forming a gate electrode in a region on a portion of the surface of the second Schottky contact layer; and
performing heat treatment to diffuse the metal to the surface or the inside of the first Schottky contact layer, whereby the gate electrode is formed.

17. A method for manufacturing a heterojunction field effect transistor according to claim 16, wherein the thickness of the layer including the metal for forming the gate electrode is not less than about half of that of the second Schottky contact layer and is less than about half of the total thickness of the first Schottky contact layer and the second Schottky contact layer.

18. A method for manufacturing a heterojunction field effect transistor according to claim 16, wherein the metal for forming the gate electrode comprises platinum.

19. A method for manufacturing a heterojunction field effect transistor according to claim 16, wherein the aluminum component ratio of the first Schottky contact layer is greater than about 0.3, and the aluminum component ratio of the second Schottky contact layer is equal to or less than about 0.3.

20. A method for manufacturing a heterojunction field effect transistor according to claim 16, wherein the channel layer is formed of undoped In_{0.2}Ga_{0.8}As, the carrier supply layer is formed of silicon doped Al_{0.25}Ga_{0.75}As, the first Schottky contact layer is formed of undoped Al_{0.9}Ga_{0.1}As, the second Schottky contact layer is formed of silicon doped Al_{0.2}Ga_{0.8}As, the semiconductor substrate is formed of semi-insulating GaAs, and the gate electrode is made of platinum.
